(19) United States
(12) Patent Application Publication
(10) Pub. No.: US 2022/0003818 A1
(43) Pub. Date: Jan. 6, 2022

(54) CROSSTALK PATTERN DETECTING DEVICE AND DETECTING METHOD

(71) Applicant: TCL CHINA STAR OPTOELECTRONICS TECHNOLOGY CO., LTD., Shenzhen, Guangdong (CN)

(72) Inventor: Guangxing XIAO, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 16/640,812

(22) PCT Filed: Jan. 10, 2020
(86) PCT No.: PCT/CN2020/071394

§ 371 Date: Feb. 21, 2020

(30) Foreign Application Priority Data
Dec. 24, 2019 (CN) 201911348967.8

(51) Int. Cl. G01R 31/3181; G09G 3/00

(52) U.S. Cl. CPC G01R 31/3181; G02F 1/1309; G09G 3/006

(57) ABSTRACT

A crosstalk pattern detecting device and a detecting method are provided by the application. The conventional combined module is implemented as an microcontroller unit in the application and parameters of crosstalk pattern detecting modes are updated during non-display period of a display panel so that a number of the detected patterns can be increased without changing the hardware, and as a result, hardware resources can be saved.

### BACKGROUND OF INVENTION

### Field of Invention

The application relates to the field of display technologies, and particularly relates to a crosstalk pattern detecting device and a detecting method based on time-sharing processing.

### Description of Prior Art

Thin film transistors (TFTs) have been main driving elements in present liquid crystal displays (LCDs) and directly affect the displaying performance of the tablet display devices.

Crosstalk in TFF-LCDs in prior art refers to a small special pattern on a display screen with monochrome background, which causes changes in brightness of adjacent horizontal areas or vertical areas. For example, in interfaces of early WINDOWS operating systems, this kind of crosstalk easily occurs when the WINDOWS operating systems boot up or shut down. According to different positions affected by the crosstalk, crosstalk of TFT-LCDs is divided into vertical crosstalk and transverse crosstalk. Vertical crosstalk refers to a deviation from a background brightness of upper part and lower part of the window when a black window (or a white window) is displayed at the background brightness of a medial gray scale. The transverse crosstalk refers to a deviation from a background brightness of left part and right part of the window when a black window (or a white window) is displayed at the background brightness of a medial gray scale. Therefore, it is necessary to detect crosstalk patterns to provide a foundation for solving or reducing crosstalk after.

Please refer to FIG. 1. FIG. 1 is a structural schematic diagram of hardware of a crosstalk pattern detecting device in prior art. The crosstalk pattern detecting device comprises 6 detecting modules (a first detecting module 101 to a sixth detecting module 106) and a combined module 12. Each of the detecting modules detects a certain kind of patterns. The combined module 12 performs a selection from detecting results of the 6 detecting modules (101 to 106) according to a certain rule. As each of the detecting modules can only detect one kind of certain patterns, the crosstalk pattern detecting device in prior art can only detect 6 patterns. If an increase of the number of the detected patterns is required, then the number of the detecting modules should be increased, which leads to a more complex design of hardware of the devices and a higher cost.

### SUMMARY OF INVENTION

A crosstalk pattern detecting device and detecting method are provide by embodiments of the application. The number of detected patterns can be increased, hardware resources can be saved and cost down can be achieved without changing the hardware.

A crosstalk pattern detecting device is provided, comprising:

a plurality of detecting modules, wherein each of the detecting modules is configured to perform pattern detection on a display panel according to a preset target parameter in a display period of the display panel to acquire a detected data; and a microcontroller unit electrically connected to all of the detecting modules, wherein the microcontroller unit is configured to perform a selection from all of the detected data according to a preset rule and configured to identify all of the detected data in a non-display period of the display panel, and the microcontroller unit updates target parameters of corresponding detecting modules when the detected data is identified as a first result, keep the target parameters of corresponding detecting modules or corresponding group of the detecting modules unchanged when the detected data is identified as a second result.

A crosstalk pattern detecting device is also provided, comprising: a plurality of detecting modules, wherein each of the detecting modules is configured to perform pattern detection on a display panel according to a preset target parameter to acquire a detected data in a first period; and a microcontroller unit electrically connected to all of the detecting modules, wherein the microcontroller unit is configured to perform a selection from all of the detected data according to a preset rule, and in a second period the microcontroller unit is configured to update target parameters of the detecting modules whose detected data is a first result to restart the pattern detection.

A crosstalk pattern detecting method, comprising steps of: (1) performing pattern detection on a display panel according to corresponding preset target parameters using a plurality of detecting modules to acquire a detected data in a first period; (2) performing a selection from all of the detected data according to a preset rule using a microcontroller unit; and (3) updating the target parameters of the detecting modules whose detected data is a first result and returning to the step (1) to perform the pattern detection again using the microcontroller unit in a second period.

The conventional combined module is implemented as a microcontroller unit (MCU) in the application and parameters of crosstalk pattern detecting modes are updated in non-display period of a display panel (VS_blank period) so that the crosstalk pattern detection can be processed flexibly and reliably and the number of the detected patterns can be increased. As a result, hardware resources can be saved.

### BRIEF DESCRIPTION OF DRAWINGS

In order to more clearly illustrate the technical solution of embodiments of this application, a brief description of the drawings that are necessary for the illustration of the embodiments of this application will be given as follows. Obviously, the drawings described below show only some embodiments of this disclosure, and a person having ordinary skill in the art may also obtain other drawings based on the drawings described without making any creative effort.

FIG. 1 is a structural schematic diagram of hardware of a pattern detecting device in prior art.

FIG. 2 is a structural schematic diagram of a pattern detecting device of one embodiment of the application.

FIG. 3 is a flow chart of a pattern detecting method of the application.

FIG. 4 is an implemented flow chart of a second period of the pattern detecting method of the application.

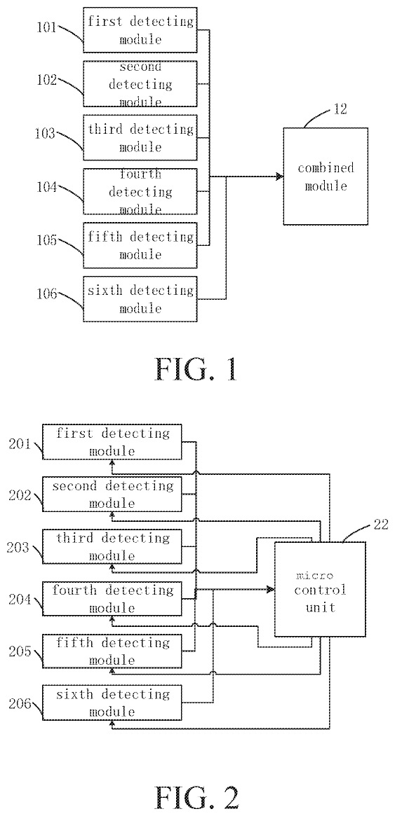

### DETAILED DESCRIPTION OF PREFERRED EMBODIMENTS

Embodiments of the present application will be described in detail below. Examples of the embodiments are shown in the drawings, wherein the same or similar reference numbers represent the same or similar components or components with the same or similar functions from beginning to end. The terms “first”, “second”, “third” and the like (if any) in the description, claims and the drawings of the application are configured to distinguish similar objects, and not necessary to describe a specific order or sequence. It should be understood that objects described like that can be interchanged while appropriate. In the description of this application, “a plurality of” means two or more than two, unless clearly specified. In addition, the terms “include” and “have” and any deformation of them are intended to cover the inclusion without exclusion. The direction terms mentioned in the application, such as: up, down, left, right, front, back, inside, outside, side, etc., are only directions referring to the drawings.

In the description of the application, it should be noted that unless clearly specified and defined, the terms “installation”, “linkage” and “connection” should be understood in a broad sense, for example, it can be fixed connection, detachable connection, or integrate connection; it can be mechanical connection, electrical connection or mutual communication; it can be direct connection or indirect connection through intermedia, and it can be internal connection of two components or the interaction between two components. For those of ordinary skill in the art, the specific meaning of the above terms in the application can be understood according to the specific situation.

A method of detecting whether crosstalk exists in images is provided by the application. The conventional combined module is implemented as a MCU (microcontroller unit, a chip-sized computer) in the application and parameters of crosstalk pattern detecting modes are updated in non-display period of a display panel (VS_blank period) so that the crosstalk pattern detection can be processed flexibly and reliably and the number of the detected patterns can be increased, and as a result hardware resources can be saved.

The following is an illustration by taking crosstalk pattern detection using 6 detecting modules as an example. That is to say, no change is made to configuration of the detection modules in the detecting devices in prior art in this application so as to avoid hardware setting changes as much as possible. It should be noted that the number of the detecting modules in the crosstalk pattern detecting device of this application could be another number as long as needs of detecting and hardware settings are met.

FIG. 2 is a structural schematic diagram of a pattern detecting device of one embodiment of the application. The crosstalk pattern detecting device comprises a plurality of detecting modules (a first detecting module 201 to a sixth detecting module 206) and a microcontroller unit 22.

Each of the detecting modules (201-206) is configured to perform pattern detection on a display panel according to a preset target parameter to acquire a detected data in a first period. That is to say, each of the detecting modules detects a certain kind of crosstalk patterns. And the first period is a display period of the display panel. The crosstalk patterns that need to be detected using the detecting modules can be established by allocating the target parameters. A setting of different parameters represents detection of different crosstalk patterns. The configuration of target parameters can be fulfilled using the microcontroller unit 22. A specific configuration way can refer to the prior art.

The microcontroller unit 22 is electrically connected to all of the detecting modules (201 to 206) and configured to perform a selection from all of the detected data according to a preset rule, and in a second period, the microcontroller unit 22 is configured to update the target parameters of the detecting modules whose detected data is a first result to restart the pattern detection. Herein, the selection from all of the detected data of the microcontroller unit 22 can be performed in the first period or in the second period. The restarted pattern detection, after the update of the target parameters, can be performed in a next first period. Herein, the first period is a display period of the display panel and the second period is a non-display period of the display panel (VS_blank period).

The rule of how the microcontroller unit 22 performs the selection from all of the detected data can refer to prior designs. For example, the selecting rule is designed according to characteristics of display panels and by taking whether the crosstalk patterns have a bad effect on quality of display panels into consideration. For example, the first detecting module 201 to the fifth detecting module 205 are selected to construct a group of detecting modules, the detected data acquired using the first detecting module 201 to the fifth detecting module 205 are calculated, and a calculated result is calculated with the detected data acquired using the sixth detecting module 206 to acquire a combined data. The calculation may be an AND operation or an OR operation, and so on.

In the second period, the microcontroller unit 22 updates the target parameters of the detecting modules whose detected data is a first result, keeps the target parameters of detecting modules or a corresponding group of the detecting modules whose detected data is a second result unchanged, and then restarts pattern detection. Herein, the first result is defined as detection failure of each of the detecting modules, and the second result is defined as detection success of each of the detecting modules. For example, the microcontroller unit 22 can identify detection as success when a detected data of 1 which is an output using the detecting modules or the group of detecting modules is received, and as a result the target parameters of the detecting modules or the group of detecting modules are kept unchanged. Otherwise the microcontroller unit 22 can identify detection as failure, and as a result the target parameters of corresponding detecting modules are required to be updated so as to start new crosstalk pattern detection.

In a further embodiment, the microcontroller unit 22 is further configured to count a number of data invalid indicating signals and determine that the display panel enters the second period when a count value is greater than or equal to a preset threshold. Specifically, the data invalid indicating signals indicate that a video data is a low level and data valid indicator signals indicate that the video data is a high level. The fact that the display panel enters the VS_blank period can be determined based on the fact that counted number of corresponding low level is greater than or equal to a preset threshold. Herein, the threshold has to be large enough to avoid incorrect operation.

The parameters of crosstalk patterns detecting modes are updated in non-display period of a display panel (VS_blank period) in the application so that the number of detected patterns can be increased and hardware resources can be saved without changing the hardware.

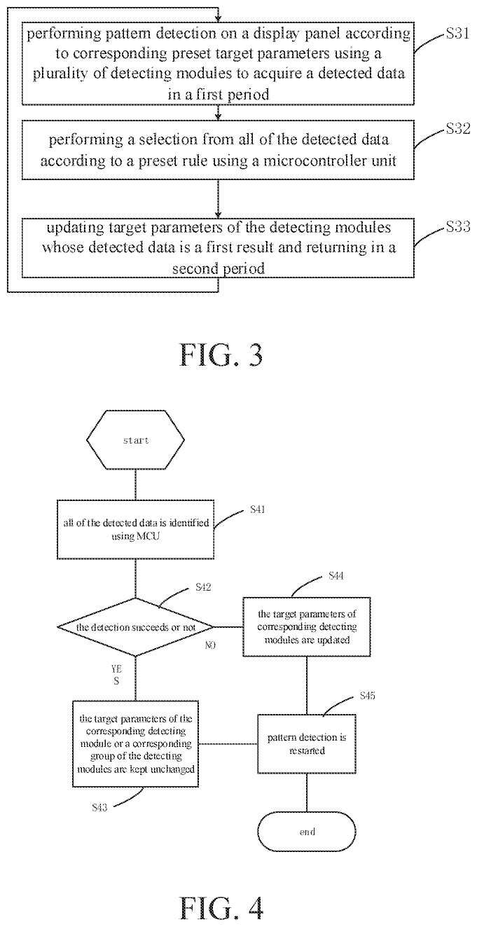

Please refer to FIG. 3. FIG. 3 is a flow chart of a crosstalk pattern detecting method of the application. The crosstalk pattern detecting method comprises steps of: step S31 of performing pattern detection on a display panel according to corresponding preset target parameters using a plurality of detecting modules to acquire a detected data in a first period; step S32 of performing a selection from all of the detected data according to a preset rule using a microcontroller unit; and step S33 of updating target parameters of the detecting modules whose detected data is a first result and returning to the step S31 to perform the pattern detection again using the microcontroller unit in a second period.

Herein the first period is a display period of the display panel and the second period is a non-display period (VS_blank period) of the display panel. In a further embodiment, the number of data invalid indicating signals can be counted and the fact that the display panel enters the second period can be determined when a count value is greater than or equal to a preset threshold. This step can be completed using the microcontroller unit or other hardware. Specifically, the data invalid indicating signals indicate that a video data is a low level and a data valid indicator signals indicate that the video data is a high level. The fact that the display panel enters the VS_blank period can be determined based on the fact that counted number of corresponding low level is greater than or equal to a preset threshold. Herein, the threshold has to be large enough to avoid incorrect operation.

Specifically, 6 detecting modules can be applied for crosstalk pattern detection. In a first period, each of the detecting modules performs pattern detection on a display panel according to a corresponding preset target parameter to acquire a detected data. That is to say, each of the detecting modules detects a certain kind of crosstalk patterns. The crosstalk patterns that need to be detected using the detecting modules can be established by allocating the target parameters. A setting of different parameters represents detection of different crosstalk patterns. The configuration of target parameters can be fulfilled using the microcontroller unit 22 or other hardware. A specific configuration way can refer to prior art.

The rule of how a microcontroller unit performs the selection from all of the detected data can refer to prior designs. For example, the selection rule is designed according to characteristics of display panels and by taking whether the crosstalk patterns have a bad effect on quality of the display panels into consideration. For example, some of the detecting modules are selected to construct a group of detecting modules. The detected data acquired using the group of detecting modules is calculated, and a calculated result is calculated with the detected data acquired using rest of the detecting modules or another group of detecting modules to acquire a combined data. The calculation maybe an AND operation or an OR operation, and so on. Herein, the selection from all of the detected data of the microcontroller unit can be performed in the first period or in the second period.

In the second period, the non-display period (VS_blank period) of the display panel, all of the detected data are identified using the microcontroller unit. The target parameters of corresponding detecting modules are updated when the detected data is identified as a first result, and the target parameters of corresponding detecting modules or a corresponding group of the detecting modules are kept unchanged when the detected data is identified as a second result. Herein, the first result is defined as detection failure of each of the detecting modules, and the second result is defined as detection success of each of the detecting modules. For example, the microcontroller unit can identify detection as success when a detected data 1 which is an output using the detecting modules or the group of detecting modules is received, and as a result the target parameters of the detecting modules or the group of detecting modules are kept unchanged. Otherwise the microcontroller unit 22 can identify detection as failure, and as a result, the target parameters of corresponding detecting modules are required to be updated so as to start new crosstalk pattern detection. The restarted pattern detection, after the update of the target parameters, can be performed in a next first period.

Please refer to FIG. 4. FIG. 4 is an implemented flow chart of a second period of a pattern detecting method of the application. Specifically, in VS_blank period, as illustrated in step S41, all of the detected data (including a single detected data and a combined detected data) is identified using the MCU; as illustrated in step S42, whether the detection succeeds or not is determined according to the identified result; as illustrated in step S43, if the detection succeeds, the target parameters of the corresponding detecting module or a corresponding group of the detecting modules are kept unchanged; as illustrated in step S44, if the detection fails, the target parameters of corresponding detecting modules are updated; and as illustrated in step S45, then the pattern detection is restarted. Herein, the restarted pattern detection, after the update of the target parameters, can be performed in a next display period of the display panel.

It can be understood that for those skilled in the art, equivalent replacements or changes can be made according to the technical scheme of the application and the invention concept, and all these changes or replacements shall belong to the scope of protection of the claims attached to the application.

What is claimed is:

1. A crosstalk pattern detecting device, comprising:
a plurality of detecting modules, wherein each of the detecting modules is configured to perform pattern detection on a display panel according to a preset target parameter in a display period of the display panel to acquire a detected data; and
a microcontroller unit electrically connected to all of the detecting modules, wherein the microcontroller unit is configured to perform a selection from all of the detected data according to a preset rule and configured to identify all of the detected data in a non-display period of the display panel, the microcontroller unit updates target parameters of corresponding detecting modules when the detected data is identified as a first result, and the microcontroller unit keeps the target parameters of the corresponding detecting modules or a corresponding group of the detecting modules unchanged when the detected data is identified as a second result.

2. The crosstalk pattern detecting device of claim 1, wherein the microcontroller unit is further configured to count a number of data invalid indicating signals and determine that the display panel enters the non-display period when a count value is greater than or equal to a preset threshold.

3. The crosstalk pattern detecting device of claim 1, wherein the microcontroller unit is further configured to allocate the target parameters to establish crosstalk patterns that need to be detected by the detecting modules.

4. The crosstalk pattern detecting device of claim 1, wherein a number of the detecting modules is 6.

5. The crosstalk pattern detecting device of claim 1, wherein the microcontroller unit is configured to perform the selection from all of the detected data in the display period of the display panel.

6. The crosstalk pattern detecting device of claim 1, wherein the microcontroller unit is configured to perform the selection from all of the detected data in the non-display period of the display panel.

7. The crosstalk pattern detecting device of claim 1, wherein the preset rule is that the microcontroller unit calculates the detected data acquired using some of the detecting modules and calculates a calculated result with the detected data acquired using rest of the detecting modules.

8. The crosstalk pattern detecting device of claim 1, wherein the first result is defined as detection failure of each of the detecting modules, and the second result is defined as detection success of each of the detecting modules.

9. A crosstalk pattern detecting device comprising:
a plurality of detecting modules, wherein each of the detecting modules is configured to perform pattern detection on a display panel according to a preset target parameter to acquire a detected data in a first period; and
a microcontroller unit electrically connected to all of the detecting modules, wherein the microcontroller unit is configured to perform a selection from all of the detected data according to a preset rule, and in a second period the microcontroller unit is configured to update target parameters of the detecting modules whose detected data is a first result to restart the pattern detection.

10. The crosstalk pattern detecting device of claim 9, wherein the first period is a display period of the display panel and the second period is a non-display period of the display panel.

11. The crosstalk pattern detecting device of claim 9, wherein the microcontroller unit is further configured to count a number of data invalid indicating signals and determine that the display panel enters the second period when a count value is greater than or equal to a preset threshold.

12. The crosstalk pattern detecting device of claim 9, wherein the microcontroller unit is further configured to allocate the target parameters to establish crosstalk patterns that need to be detected by the detecting modules.

13. The crosstalk pattern detecting device of claim 9, wherein in the second period, the microcontroller unit is further configured to identify all of the detected data and update target parameters of corresponding detecting modules when the detected data is identified as a first result, and the microcontroller unit keeps the target parameters of the corresponding detecting modules or a corresponding group of the detecting modules unchanged when the detected data is identified as a second result.

14. The crosstalk pattern detecting device of claim 13, wherein the first result is defined as detection failure of each of the detecting modules, and the second result is defined as detection success of each of the detecting modules.

15. The crosstalk pattern detecting device of claim 9, wherein the preset rule is that the microcontroller unit calculates the detected data acquired using some of the detecting modules and calculates a calculated result with the detected data acquired using rest of the detecting modules.

16. A crosstalk pattern detecting method, comprising steps of:
(1) performing pattern detection on a display panel according to corresponding preset target parameters using a plurality of detecting modules to acquire a detected data in a first period;
(2) performing a selection from all of the detected data according to a preset rule using a microcontroller unit; and
(3) updating target parameters of the detecting modules whose detected data is a first result and returning to the step (1) to perform the pattern detection again using the microcontroller unit in a second period.

17. The crosstalk pattern detecting method of claim 16, wherein the first period is a display period of the display panel and the second period is a non-display period of the display panel.

18. The crosstalk pattern detecting method of claim 16, further comprising counting a number of data invalid indicating signals and determining that the display panel enters the second period when a count value is greater than or equal to a preset threshold.

19. The crosstalk pattern detecting method of claim 16, wherein crosstalk patterns that need to be detected using the detecting modules are established by allocating the target parameters.

20. The crosstalk pattern detecting method of claim 16, wherein the step (2) further comprises identifying all of the detected data using the microcontroller unit, updating target parameters of corresponding detecting modules when the detected data is identified as the first result, and keeping the target parameters of the corresponding detecting modules or a corresponding group of the detecting modules unchanged when the detected data is identified as a second result.
